(19) United States
(12) Patent Application Publication
(10) Pub. No.: US 2009/0152561 A1
(43) Pub. Date: Jun. 18, 2009

(54) ORGANIC THIN FILM TRANSISTOR DISPLAY SUBSTRATE, METHOD OF FABRICATING THE SAME, AND DISPLAY APPARATUS HAVING THE SAME

(75) Inventors: Soo-Wan Yoon, Suwon-si (KR); Chai Chong-chul, Seoul (KR)

Correspondence Address: Haynes and Boone, LLP;IP Section, 2323 Victory Avenue, SUITE 700, Dallas, TX, 75219, US

(73) Assignee: Samsung Electronics Co., Ltd.

(21) Appl. No.: 12/274,300

(22) Filed: Nov. 19, 2008

(30) Foreign Application Priority Data
Dec. 14, 2007 (KR) 2007-0130842

(51) Int. Cl. H01L 33/00

(52) U.S. Cl. 257/72; 438/29; 438/99; 257/40; 257/E33.055

(57) ABSTRACT

In an organic thin film transistor display substrate, a thin film transistor and a pixel electrode electrically connected to the thin film transistor are formed on an array substrate in which a plurality of pixel areas is defined. Also, color filters are formed in the pixel areas. Each color filter is provided with an opening formed therethrough and an active pattern of thin film transistor is received into the opening. Since the active pattern is formed on the array substrate through an inkjet method, the color filter may receive the active pattern therein in lieu of a bank pattern, thereby simplifying the structure of the organic thin film transistor display substrate and improving its productivity.

### CROSS-REFERENCE TO RELATED APPLICATION

This application claims priority to and the benefit of Korean Patent Application No. 2007-130842 filed on Dec. 14, 2007, the contents of which are herein incorporated by reference in its entirety.

### BACKGROUND

1. Technical Field

One or more embodiments of the present invention generally relate to an organic thin film transistor display substrate, a method of fabricating the same, and a display apparatus having the same. More particularly, one or more embodiments of the present invention relate to an organic thin film transistor display substrate having improved productivity, a method of fabricating the organic thin film transistor display substrate, and a display apparatus having the organic thin film transistor display substrate.

2. Description of the Related Art

In general, a display apparatus includes an array substrate and a cover substrate that is combined with the array substrate to display an image. The array substrate includes a plurality of pixel regions defined thereon, and each of the pixel regions includes a thin film transistor and a pixel electrode electrically connected to the thin film transistor.

The thin film transistor includes an active pattern and is turned on or turned off in accordance with a voltage applied to its gate electrode, causing data signals to be selectively supplied to the pixel electrode.

The active pattern includes amorphous silicon or an organic semiconductor material. In the case that the active pattern includes the organic semiconductor material, the organic semiconductor is formed on the array substrate through an inkjet method.

In general, before forming the organic semiconductor material on the array substrate through the inkjet method, in order to form the organic semiconductor material at accurate position, a bank pattern with a plurality of opening is formed on the array substrate and the organic semiconductor material is then injected into the opening.

However, when the organic semiconductor organic is formed on the array substrate using the bank pattern, additional processes of forming the bank pattern are required. Thus, the number of processes to fabricate the array substrate increases, undesirably increasing fabricating cost.

### SUMMARY

One or more embodiments of the present invention generally provide an organic thin film transistor display substrate having a simplified structure.

One or more embodiments of the present invention also generally provide a method of fabricating the thin film transistor capable of reducing fabricating cost.

One or more embodiments of the present invention also generally provide a display apparatus having the organic thin film transistor display substrate.

According to an exemplary embodiment of the present invention, an organic thin film transistor display substrate includes a substrate including a plurality of pixel areas defined thereon, an organic thin film transistor arranged in each pixel area and including an organic active pattern, a color filter arranged in each pixel area and provided with a first opening that is filled with the organic active pattern, and a pixel electrode electrically connected to the organic thin film transistor and formed on the color filter.

According to an exemplary embodiment of the present invention, a method of fabricating an organic thin film transistor display substrate includes preparing a substrate in which a plurality of pixel areas is defined, forming a gate electrode on the array substrate, forming a gate insulating layer on the gate electrode, forming source and drain electrodes spaced apart from each other on the gate insulating layer, forming a color filter through which a first opening is formed on the source electrode and the drain electrode to expose the source electrode and the drain electrode, and forming an organic active pattern in the first opening.

According to an exemplary embodiment of the present invention, a display apparatus includes a first substrate including a plurality of pixel areas defined thereon, an organic thin film transistor arranged in each pixel area and including an organic active pattern, a color filter arranged in each pixel area and provided with a first opening filled with the organic active pattern, a pixel electrode arranged on the color filter and electrically connected to the organic thin film transistor, and a second substrate facing the first substrate.

According to the above, when the color filter is formed on the array substrate, the color filter is partially removed from the active area to form the opening therethrough and the opening is filled with an organic semiconductor material, thereby forming the organic semiconductor layer.

### BRIEF DESCRIPTION OF THE DRAWINGS

The above and other advantages of embodiments of the present invention will become readily apparent by reference to the following detailed description when considered in conjunction with the accompanying drawings wherein:

FIG. 1A is a perspective view showing a liquid crystal display according to one or more exemplary embodiments of the present invention;

FIG. 1B is an enlarged plan view of a portion ‘A’ of FIG. 1A;

FIG. 2 is a cross-sectional view taken along a line I-I′ of FIG. 1;

FIGS. 3A to 7A are plan views illustrating a method of fabricating the array substrate of FIG. 2 according to one or more exemplary embodiments of the present invention; and

FIGS. 3B to 7B are cross-sectional views taken along a line II-II′ of each of FIGS. 3A to 7A.

### DESCRIPTION OF THE EMBODIMENTS

It will be understood that when an element or layer is referred to as being “on”, “connected to” or “coupled to” another element or layer, it may be directly on, connected or coupled to the other element or layer, or intervening elements or layers may be present. In contrast, when an element is referred to as being “directly on,” “directly connected to” or “directly coupled to” another element or layer, there are no intervening elements or layers present. Like reference numerals refer to like elements throughout. As used herein, the term “and/or” includes any and all combinations of one or more of the associated listed items.

It will be further understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein may be interpreted accordingly.

The terminology used herein is for the purpose of describing particular embodiments of the invention only and is not intended to be limiting of other embodiments of the invention. As used herein, the singular forms, “a”, “an” and “the” are intended to include the plural forms as well, unless the context clearly indicates otherwise. It will be further understood that the terms “includes” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as are commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, one or more exemplary embodiments of the present invention will be explained in detail with reference to the accompanying drawings.

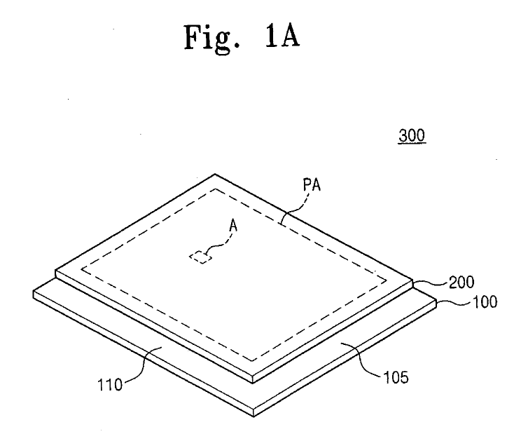

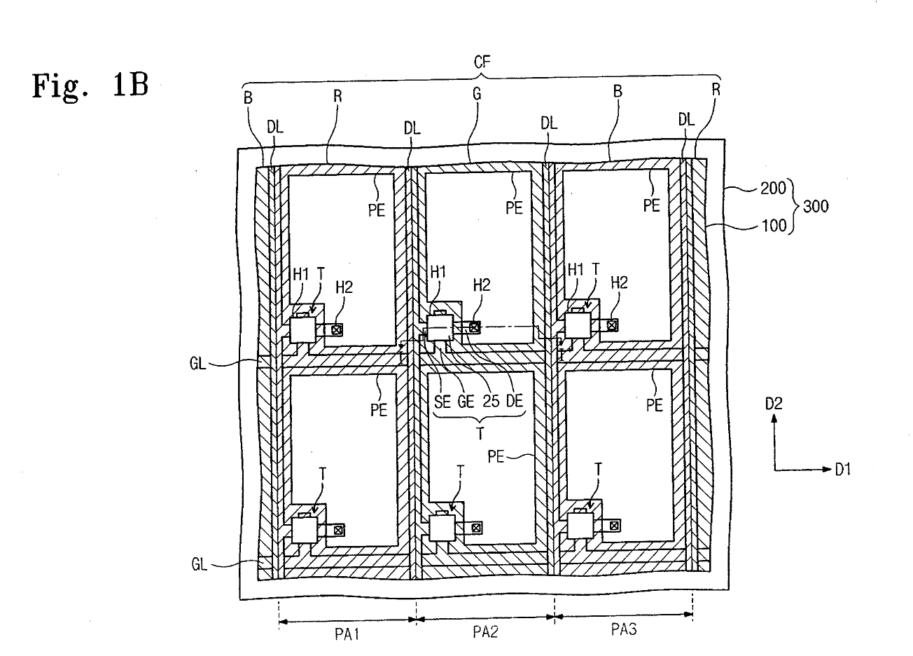

FIG. 1A is a perspective view showing a liquid crystal display according to one or more exemplary embodiments of the present invention, and FIG. 1B is an enlarged plan view of a portion ‘A’ of FIG. 1A. As shown in FIG. 1A, the portion ‘A’ is a portion of a pixel area PA.

Referring to FIGS. 1A and 1B, a liquid crystal display 300 includes an array substrate 100, a cover substrate 200 facing the array substrate 100, and liquid crystals (not shown) interposed between the array substrate 100 and the cover substrate 200.

The array substrate 100 includes a plurality of pixel areas PA defined thereon. The pixel areas PA serve as a display area in which an image is displayed. Each of the pixel areas PA may include an organic thin film transistor T and a pixel electrode PE electrically connected to the organic thin film transistor T. The pixel electrode PE and the organic thin film transistor may be arranged in a matrix configuration along first and second directions D1 and D2.

Also, the array substrate 100 includes a data bonding area 110 and a gate bonding area 105 that may be defined outside the pixel area PA. The array substrate 100 may be electrically connected to a gate driver (not shown) in the gate bonding area 105 and may also be electrically connected to a data driver (not shown) in the data bonding area 110. Therefore, the array substrate 100 may receive a gate signal from the gate driver to switch the organic thin film transistor T and may receive a data signal from the data driver to supply the data signal to the pixel electrode PE.

A plurality of gate lines GL may be arranged on the array substrate 100 along the second direction D2 and extend in the first direction D1, and a plurality of data lines DL may be arranged on the array substrate 100 along the first direction D1 and extend in the second direction D2.

The organic thin film transistor T may include a source electrode SE, a drain electrode DE, a gate electrode GE, and an organic semiconductor layer 25 that serves as an active pattern. The gate electrode GE may be branched from the gate line GL, the source electrode SE may be branched from the data line DL, and the drain electrode DE may be spaced apart from the source electrode SE while interposing the organic semiconductor layer 25 therebetween.

The pixel electrode PE may be electrically connected to the drain electrode DE of the organic thin film transistor T. Thus, when the organic thin film transistor T is turned on in response to a gate voltage supplied through the gate line GL, the data signal supplied from data line DL is applied to the pixel electrode PE through the source electrode SE, the organic semiconductor layer 25 and the drain electrode DE.

The organic semiconductor layer 25 may include an organic material having high flexibility and conductivity, such as pentacene, to serve as the active pattern of the organic thin film transistor T.

Color filters CF may be formed on the array substrate 100. The color filters CF may include a red color filter R, a green color filter G and a blue color filter B. For the convenience of explanation of the color filters CF, the pixel area PA may be divided into a first pixel area PA1, a second pixel area PA2, and a third pixel area PA3.

The first pixel area PA1, the second pixel area PA2 and the third pixel area PA3 may be sequentially arranged in the first direction D1 (i.e., a row direction), so that the first pixel area PA1 is neighbored with the second pixel area PA2, the second pixel area PA2 is neighbored with the third pixel area PA3, and the third pixel area PA3 is spaced apart from the first pixel area PA1 while interposing the second pixel area PA2 between the first and the third pixel areas PA1 and PA3.

The red color filter R may be arranged in the first pixel area PA1, the green color filter G may be arranged in the second pixel area PA2, and the blue color filter B may be arranged in the third pixel area PA3. Although not shown in FIGS. 1A and 1B, the red color filter R, the green color filter G and the blue color filter B may be repeatedly arranged in the first direction D1.

In the present exemplary embodiment of the invention, the red color filter R, the green color filter G and the blue color filter B are repeatedly arranged along the first direction D1, but the red color filter R, the green color filter G and the blue color filter B may be arranged in various combinations. For example, the red color filter R, the green color filter G and the blue color filter B may be repeatedly arranged along the second direction D2 or arranged along both the first direction D1 and the second direction D2.

Meanwhile, a first opening H1 and a second opening H2 may be formed through each of the red color filter R, the green color filter G and the blue color filter B. In the red color filter R, the first opening H1 may be formed by removing a portion of the red color filter R overlapping the gate electrode GE, and the second opening H2 may be formed by removing a portion of the red color filter R overlapping the drain electrode DE. The organic semiconductor layer 25 may be formed to fill the first opening Hi and be electrically connected to the source electrode SE and the drain electrode DE through the first opening H1. Also, the pixel electrode PE may be formed to fill the second opening H2, so that the pixel electrode PE is electrically connected to the drain electrode DE.

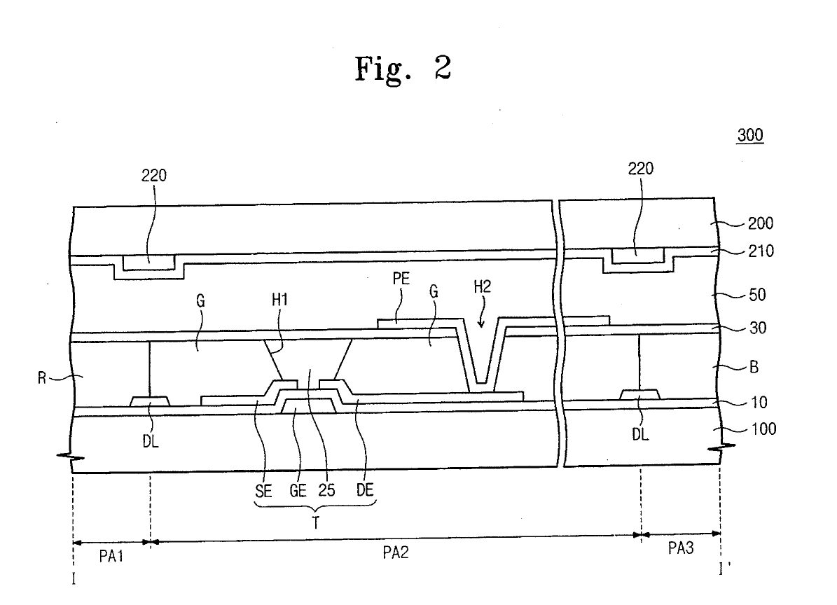

FIG. 2 is a cross-sectional view taken along a line I-I′ of FIG. 1.

Referring to FIG. 2, the organic thin film transistor T including the source electrode SE, the drain electrode DE and the organic semiconductor layer 25 is arranged on the array substrate 100, and the pixel electrode PE electrically connected to the drain electrode DE is also formed on the array substrate 100.

The organic semiconductor layer 25 may be formed on the source electrode SE and the drain electrode DE and may partially overlap the source electrode SE and the drain electrode DE when viewed in a plan view, thereby making contact with the source electrode SE and the drain electrode DE.

Also, the red color filter R, the green color filter G and the blue color filter B may be arranged on the array substrate 100. More specifically, the red color filter R may be arranged in the first pixel area PA1, the green color filter G may be arranged in the second pixel area PA2, and the blue color filter B may be arranged in the third pixel area PA3. The red color filter R may include an organic material of a red color, the green color filter G may include an organic material of a green color, and the blue color filter B may include an organic material of a blue color.

The first and second openings H1 and H2 may be formed through the green color filter G formed in the second pixel area PA2, and the first opening H1 may be filled with the organic semiconductor layer 25. The first opening H1 may be formed by partially removing the green color filter G overlapping the gate electrode GE, the source electrode SE, and the drain electrode DE. Therefore, the organic semiconductor layer 25 in the first opening H1 may overlap the gate electrode GE when viewed in a plan view and may make contact with a gate insulating layer 10 formed on the gate electrode GE, the source electrode SE, and the drain electrode DE.

The organic semiconductor layer 25 may be positioned at an uppermost portion of the organic thin film transistor T, and a lower portion of the organic semiconductor layer 25 may be located between the source electrode SE and the drain electrode DE. Accordingly, the distance between the uppermost portion of the organic thin film transistor T and the array substrate 100 may be greater than that between the array substrate 100 and one of the gate electrode GE, the source electrode SE, and the drain electrode DE.

The second opening H2 may be formed through the green color filter G by partially removing the green color filter G overlapping the drain electrode DE. The pixel electrode PE may make contact with the drain electrode DE through the second opening H2, thereby electrically connecting the pixel electrode PE to the drain electrode DE.

The gate insulating layer 10 may be formed under the data line DL, the drain electrode DE, and the source electrode SE and on the array substrate 100 to cover the gate electrode GE. In the present exemplary embodiment of the invention, the gate insulating layer 10 may include an inorganic material such as silicon nitride, silicon oxide, or may include an organic material.

Also, the array substrate 100 may include an insulating interlayer 30 formed under the pixel electrode PE to cover the organic semiconductor layer 25, the red color filter R, the green color filter G and the blue color filter B. The insulating interlayer 30 may prevent the red, green, and blue color filters R, G, and B from directly contacting a liquid crystal 50, thereby preventing movement of impurities in the color filters from contaminating the liquid crystal 50.

The cover substrate 200 may include a common electrode 210 and a black matrix 220. The black matrix 220 may include a light-blocking material to block light from passing through a region between color filters having different colors. That is, the black matrix 220 may be formed in a region adjoining the first pixel area PA1 and the second pixel area PA2 and a region adjoining the second pixel area PA2 and the third pixel area PA3. Also, the common electrode 210 may include a transparent conductive material such as indium tin oxide (ITO) or indium zinc oxide (IZO) to generate an electric field with the pixel electrode PE. In the present exemplary embodiment of the invention, since the red color filter R, the green color filter G and the blue color filter B may be formed on the array substrate 100, the color filters may not be formed on the cover substrate 200.

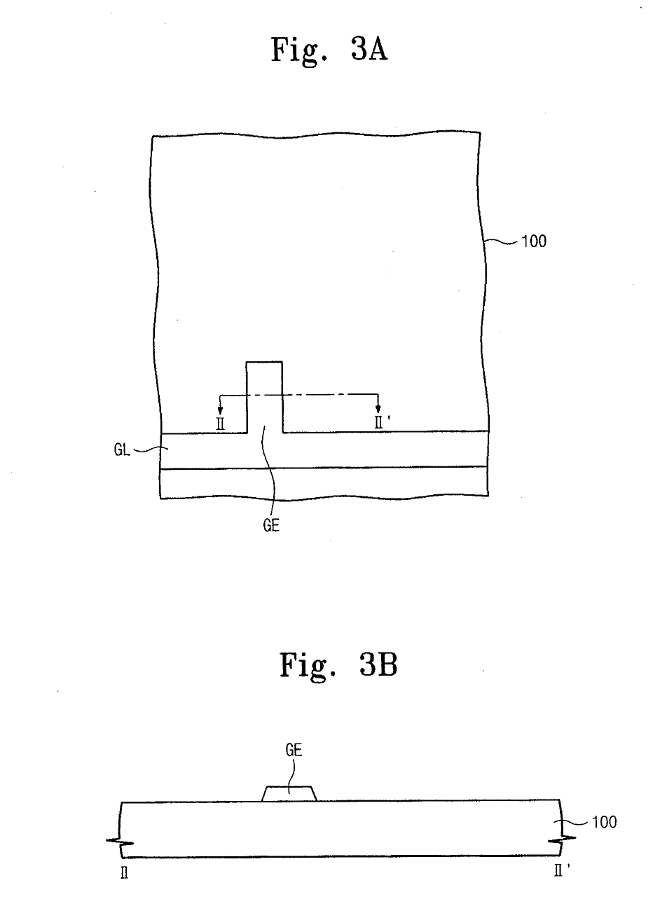

FIG. 3A to FIG. 7A are plan views illustrating a method of fabricating the array substrate 100 of FIG. 2 according to one or more exemplary embodiments of the present invention, and FIG. 3B to FIG. 7B are cross-sectional views taken along a line II-II′ of each of FIG. 3A to FIG. 3B. Also, FIG. 3A to FIG. 7A show the second pixel area PA2 (see FIG. 1B) of the array substrate 100 (see FIG. 1B).

Referring to FIGS. 3A and 3B, the gate line GL and the gate electrode GE branching from the gate line GL may be formed on an array substrate 100. In order to form the gate line GL and the gate electrode GE, a metal material may be deposited on the array substrate 100, and the metal material may be patterned through a photolithography method, thereby forming the gate line GL and the gate electrode GE.

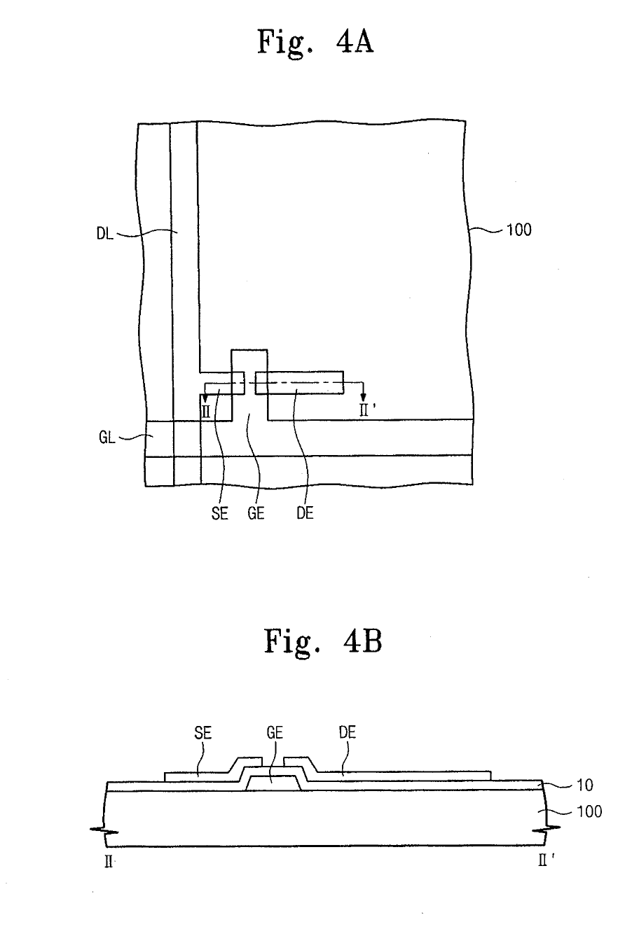

Referring to FIGS. 4A and 4B, the gate insulating layer 10 may be formed on the array substrate 100 on which the gate line GL and the gate electrode GE are formed. Also, after the gate insulating layer 10 is formed on the array substrate 100, the data line DL, the source electrode SE and the drain electrode DE may be formed on the gate insulating layer 10. Similar to the gate line GL and the gate electrode GE, the data line DL, the source electrode SE and the drain electrode DE may be formed by depositing a metal material on the array substrate 100 and patterning the metal material through a photolithography method.

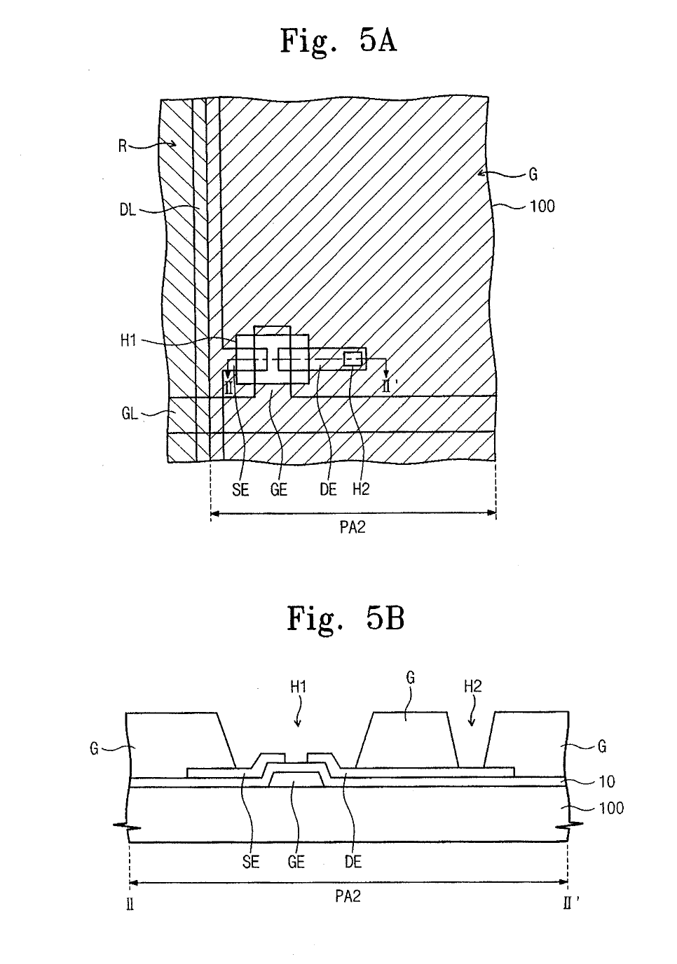

Referring to FIGS. 5A and 5B, the green color filter G through which the first opening H1 and the second opening H2 are formed may be formed in the second pixel area PA2 of the array substrate 100.

When a photoresist material (not shown) of a green color is deposited on the array substrate 100, the photoresist material may be exposed and developed to form the first opening H1 and the second opening H2 therethrough, so that the green color filter G having the first and second openings H1 and H2 may be formed on the array substrate 100.

The first opening H1 may be formed by partially removing a portion of the green color filter G overlapping the gate electrode GE, the source electrode SE, and the drain electrode DE. As a result, the gate electrode GE, the source electrode SE, and the drain electrode DE may be partially exposed through the first opening H1.

The second opening H2 may be formed by removing a portion of the green color filter G overlapping the drain electrode DE, so that the drain electrode DE may be partially exposed to the outside through the second opening H2.

Referring to FIG. 1B again, after the green color filter G is formed in the second pixel area PA2, the red color filter R may be formed in the first pixel area PA1, and the blue color filter B may be formed in the third pixel area PA3. The red color filter R and the blue color filter B may be formed using photoresist materials having red and blue colors, respectively, through substantially the same process as that of the green color filter G in the above-illustrated method.

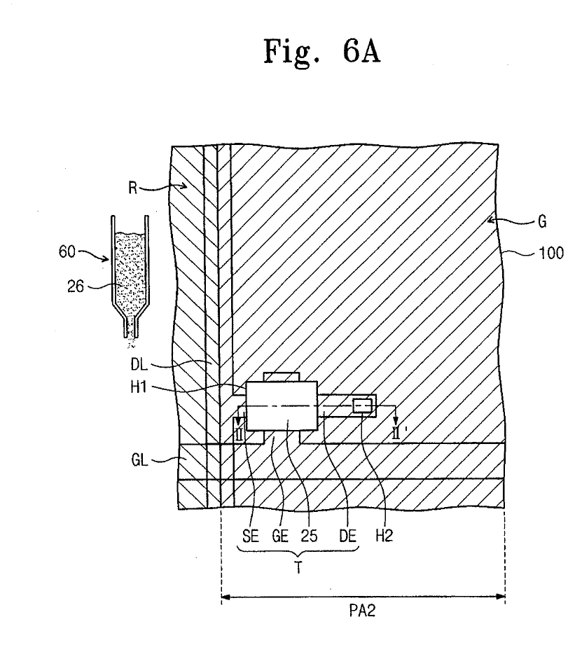

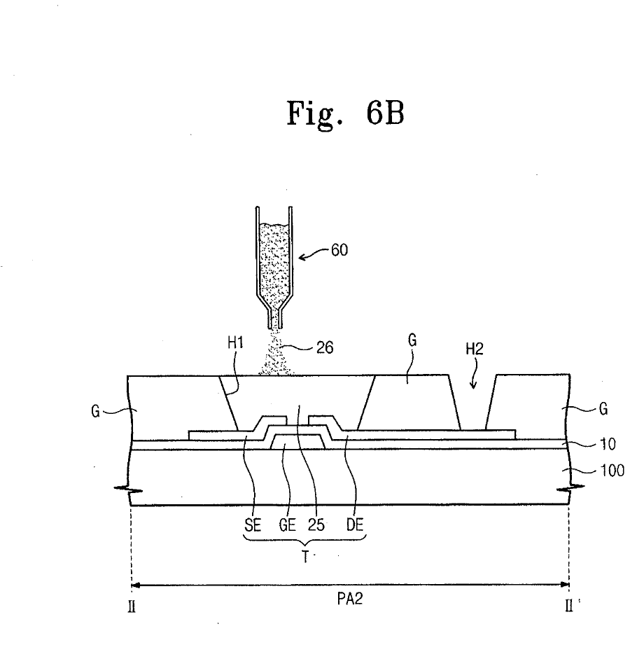

Referring to FIGS. 6A and 6B, the organic semiconductor layer 25 may be formed on the array substrate 100 on which the green color filter G is formed to fill the first opening H1 through the inkjet method. In particular, when an organic semiconductor material 26 is applied to the first opening H1 by using a dispenser 60 and the first opening H1 is filled with the organic semiconductor material 26, the organic semiconductor layer 25 may be formed in the first opening H1 as shown in FIG. 6B.

The organic semiconductor material 26 may include an organic material having high flexibility and conductivity, such as pentacene. Thus, the organic semiconductor material 26 may be sprayed to the array substrate 100 through the dispenser 60 after being contained in the dispenser 60.

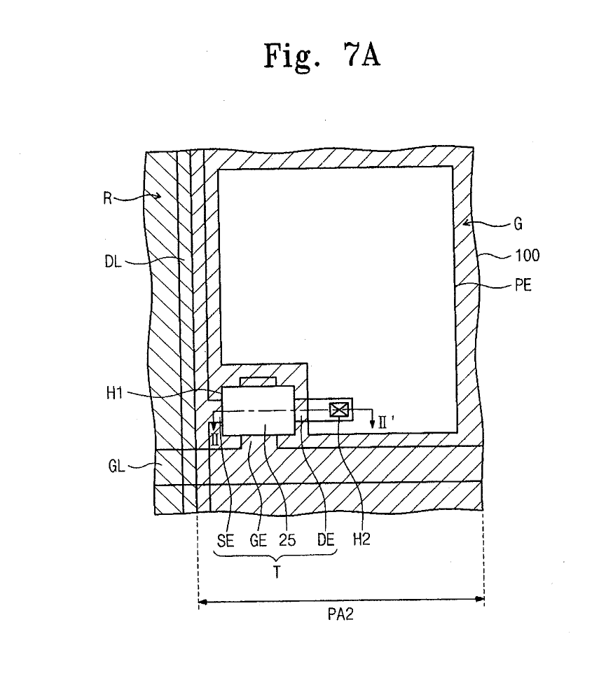

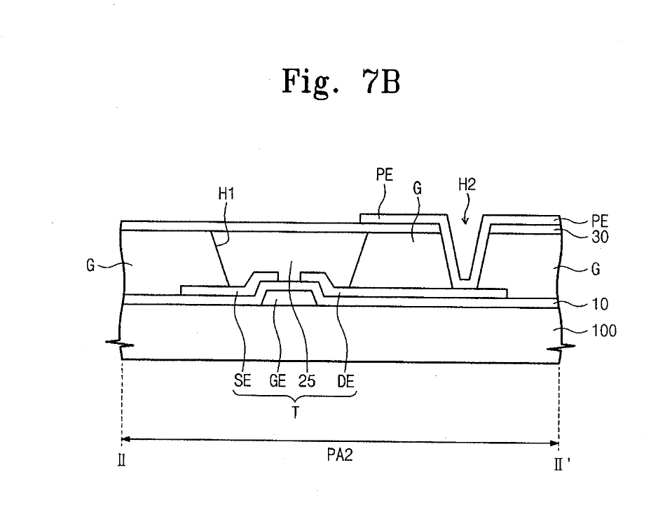

Hereinafter, a final structure of the array substrate will be explained in detail with reference to FIGS. 7A and 7B according to an exemplary embodiment of the present invention. In FIGS. 7A and 7B, the second pixel area PA2 of pixel areas PA defined on the array substrate 100 will be representatively described.

Referring to FIGS. 7A and 7B, the insulating interlayer 30 may be formed on the organic semiconductor layer 25 and the green color filter G formed on the array substrate 100. The insulating interlayer 30 may be formed over the entire surface of the array substrate 100, and a portion of the insulating interlayer 30, which is formed inside the second opening H2, may be removed such that the pixel electrode PE may make contact with the drain electrode DE without any interruption by the insulating interlayer 30.

After the insulating interlayer 30 is formed on the array substrate 100, the pixel electrode PE may be formed in the second pixel area PA2 of the array substrate 100. The pixel electrode PE may include a transparent conductive material such as indium tin oxide (ITO) or indium zinc oxide (IZO). The pixel electrode PE may be formed inside the second opening H2 and may be electrically connected to the drain electrode DE through the second opening H2.

The gate line GL and the data line DL may cross each other and may be insulated from each other to define the second pixel area PA2 on the array substrate 100. The second pixel area PA2 may include the organic thin film transistor T, the green color filter G, and the pixel electrode PE.

The organic thin film transistor T may include the gate electrode GE, the source electrode SE, the drain electrode DE, and the organic semiconductor layer 25. The gate electrode GE may be branched from the gate line GL, the source electrode SE may be branched from the data line DL, and the drain electrode DE including the same material as that of the data line DL may be spaced apart from the source electrode SE.

In the organic thin film transistor T, the organic semiconductor layer 25 may serve as the active pattern. The organic semiconductor layer 25 may include an organic material having high flexibility and conductivity, such as pentacene. The organic semiconductor layer 25 may be formed on the source electrode SE and the drain electrode DE and may overlap the gate electrode GE. Accordingly, the organic semiconductor layer 25 may be formed at the uppermost portion of the organic thin film transistor T, so that the lower portion of the organic semiconductor layer 25 may be located between the source electrode SE and the drain electrode DE.

The green color filter G through which the first opening H1 and the second opening H2 are formed may be formed in the second pixel area PA2. The first opening H1 may be formed by partially removing the green color filter G and may be positioned to correspond to the organic thin film transistor T. The first opening H1 may be filled with the organic semiconductor layer 25. The upper surface of the organic semiconductor layer 25 filled into the first opening H1 may be located at the same height as the upper surface of the green color filter G. Also, the second opening H2 that exposes the drain electrode DE therethrough may be formed by partially removing the green color filter G.

The insulating interlayer 30 may be formed on the array substrate 100 to cover the organic semiconductor layer 25 and the green color filter G. The insulating interlayer 30 may be partially removed to expose the drain electrode DE through the second opening H2.

The pixel electrode PE may be formed on the insulating interlayer 30 and may be electrically connected with the drain electrode DE through the second opening H2. The pixel electrode PE may include a transparent conductive material, such as indium tin oxide (ITO) or indium zinc oxide (IZO).

According to the above, when the color filter is formed on the array substrate, the color filter may be partially removed from the active area to form the opening therethrough and the opening may be filled with the organic semiconductor material, thereby forming the organic semiconductor layer. That is, since the color filter having the opening is on the array substrate and the color filter may serve as a bank pattern, the process of forming the bank pattern on the array substrate may be omitted, thereby simplifying the structure of the organic thin film transistor display substrate and the display apparatus having the organic thin film transistor display substrate.

Although exemplary embodiments of the present invention have been described, it is understood that embodiments of the present invention should not be limited to these exemplary embodiments but various changes and modifications may be made by one of ordinary skill in the art and be included within the spirit and scope of the present invention as hereinafter claimed.

What is claimed is:

1. An organic thin film transistor display substrate comprising:
a substrate including a plurality of pixel areas defined thereon;
an organic thin film transistor arranged in each of the pixel areas and including an organic active pattern;
a color filter arranged in each of the pixel areas and provided with a first opening filled with the organic active pattern; and
a pixel electrode arranged on the color filter and electrically connected to the organic thin film transistor.

2. The organic thin film transistor display substrate of claim 1, wherein the organic active pattern is positioned at an uppermost portion of the organic thin film transistor.

3. The organic thin film transistor display substrate of claim 2, wherein the organic thin film transistor comprises:
a gate electrode;
a source electrode overlapping the gate electrode; and
a drain electrode spaced apart from the source electrode,
wherein a lower portion of the organic active pattern is located between the source electrode and the drain electrode.

4. The organic thin film transistor display substrate of claim 3, wherein a second opening that exposes the drain electrode is formed through the color filter, and the pixel electrode is electrically connected to the drain electrode through the second opening.

5. The organic thin film transistor display substrate of claim 1, further comprising an insulating layer formed under the pixel electrode to cover the organic active pattern and the color filter.

6. The organic thin film transistor display substrate of claim 1, wherein the color filter comprises an organic material.

7. A method of fabricating an organic thin film transistor display substrate, the method comprising:
preparing a substrate including a plurality of pixel areas defined thereon;
forming a gate electrode on the substrate;
forming a gate insulating layer on the substrate to cover the gate electrode;
forming a source electrode and a drain electrode spaced apart from the source electrode on the gate insulating layer;
forming a color filter on the source electrode and the drain electrode, the color filter layer including a first opening formed therethrough to expose the source electrode and the drain electrode; and
forming an organic active pattern in the first opening.

8. The method of claim 7, wherein a lower portion of the organic active pattern is positioned between the source electrode and the drain electrode.

9. The method of claim 7, wherein the gate electrode, the source electrode, the drain electrode, and the organic active pattern define an organic thin film transistor.

10. The method of claim 9, further comprising forming a pixel electrode electrically connected to the organic thin film transistor on the color filter.

11. The method of claim 10, wherein a second opening is formed through the color filter to expose the drain electrode, and the pixel electrode is electrically connected to the drain electrode through the second opening.

12. The method of claim 7, wherein the organic active pattern is formed through an inkjet method.

13. The method of claim 7, further comprising forming an insulating layer to cover the organic active pattern and the color filter layer.

14. The method of claim 7, wherein the color filter layer comprises an organic material.

15. A display apparatus comprising:
a first substrate including a plurality of pixel areas defined thereon;
an organic thin film transistor arranged in each pixel area and including an organic active pattern;
a color filter arranged in each pixel area and provided with a first opening filled with the organic active pattern;
a pixel electrode arranged on the color filter and electrically connected to the organic thin film transistor; and
a second substrate facing the first substrate.

16. The display apparatus of claim 15, wherein the organic active pattern is positioned at an uppermost portion of the organic thin film transistor.

17. The display apparatus of claim 16, wherein the organic thin film transistor comprises:
a gate electrode;
a source electrode overlapping the gate electrode; and
a drain electrode spaced apart from the source electrode,
wherein a lower portion of the organic active pattern is positioned between the source electrode and the drain electrode.

18. The display apparatus of claim 17, wherein a second opening is formed through the color filter to expose the drain electrode and the pixel electrode is electrically connected to the drain electrode through the second opening.

19. The display apparatus of claim 15, further comprising an insulating layer formed under the pixel electrode to cover the organic active pattern and the color filter layer.

20. The display apparatus of claim 15, wherein the color filter comprises an organic material.
